(19) United States
(12) Patent Application Publication
(10) Pub. No.: US 2025/0393154 A1
(43) Pub. Date: Dec. 25, 2025

(54) Server System Storage System Storage Module

(71) Applicant: Dell Products L.P., Round Rock, TX (US)

(72) Inventors: Yen-Hsing Lin, Datong District (TW); Tingchun Kuo, Neihu District (TW); Ying-Hsien Tseng, Taipei (TW)

(21) Appl. No.: 18/753,660

(22) Filed: Jun. 25, 2024

(51) Int. Cl. H05K 7/14

(52) U.S. Cl. CPC H05K 7/1489; H05K 7/1492

(57) ABSTRACT

A storage system. The storage system includes a storage system cartridge module; and, a storage system housing, the storage system housing a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

### BACKGROUND OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a storage system with a storage module having a plurality of latching systems.

In one embodiment, the invention relates to a storage system housing for use with storage module system for an information handling system, comprising: a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

In another embodiment, the invention relates to a storage system comprising: a storage system cartridge module; and, a storage system housing, the storage system housing comprising a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

In another embodiment, the invention relates to a system comprising: a processor; a data bus coupled to the processor; and a storage system comprising a storage system cartridge module; and, a storage system housing, the storage system housing comprising a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a storage system with a plurality of latching systems.

FIG. 5 shows a perspective view of a storage system housing of a storage system.

FIG. 6 shows a perspective view of a front housing component of a storage system housing.

FIG. 7 shows a perspective view of a storage cartridge of a storage system.

FIG. 8 shows a cut away perspective view of a portion of a storage system latching system.

FIG. 9A and 9B, generally referred to as FIG. 9, show cross sectional views of a latching system when functioning in an installation configuration and a removal configuration, respectively.

### DETAILED DESCRIPTION

Various aspects of the disclosure include an appreciation that it is known to provide information handling systems with storage systems such as boot optimized storage systems. Various aspects of the disclosure include an appreciation that it is known to storage systems, such as boot optimized storage systems, which are hot swappable. Various aspects of the present disclosure include an appreciation that it is known to provide storage systems which can mount a plurality of storage components. Various aspects of the present disclosure include an appreciation that each component of the storage system often includes a respective latch mechanism for inserting and removing the storage component to the storage system housing.

Various aspects of the present disclosure include an appreciation that with known systems, a latch mechanism interacts with a respective latch engagement portion of the storage system housing. Various aspects of the present disclosure include an appreciation that with certain storage system housings there can be an issue with certain latch engagement portions when the storage component is inserted or removed from the storage system housing. Various aspects of the present disclosure include an appreciation that it is desirable to provide the latch engagement portion with a depth feature to facilitate a cam in operation and a cam out operation by the latch mechanism. For example, when the latch mechanism performs a cam in operation, a hook of the latch mechanism will push against an inside edge of the latch engagement portion, whereas when the latch mechanism performs a cam out operation, the hook of the latch mechanism will push against an outside edge of the latch engagement portion.

Various aspects of the present disclosure include an appreciation that with certain storage system housings an issue with certain latch engagement portions is especially noticeable for latch engagement portions which are positioned within a front portion of the storage system housing as compared with latch engagement portions which are positioned alone an edge of a front portion of the storage system housing. Various aspects of the present disclosure include an appreciation that with certain storage system housings an issue with certain latch engagement portions may be present because it can be difficult to punch an aperture to provide the latch engagement portion when the latch engagement portion is positioned within a front portion of the storage system housing rather than an outside surface of the storage system housing. As used herein, within a front portion of the storage system housing broadly refers to a position along the front portion of the storage system housing that is other than a position along an outside edge (e.g., a left edge or a right edge) of the storage system housing.

Accordingly, various aspects of the present disclosure include an appreciation that it would be desirable to provide a storage system housing with a latch engagement portion which includes a depth feature that does not require an aperture to be punched through the storage system housing.

A system and method are disclosed for providing a storage system with a storage system housing which includes a latch engagement portion which provides a depth feature that does not require an aperture to be punched through the storage system housing.

In certain embodiments, the latch engagement portion is configured to include a first segment and a second segment, where the first segment and the second segment combine to provide a depth feature. In certain embodiments, the first segment and the second segment provide a first contact surface and a second contact surface for a latching mechanism. In certain embodiments, the first segment provides the latch engagement portion with an inside contact surface for the latching mechanism. In certain embodiments, the second segment provides the latch engagement portion with an outside contact surface for a latching mechanism.

In certain embodiments, the first segment protrudes from a face of the storage system housing by a first amount, and the second segment protrudes from the face of the storage system housing by a second amount. In certain embodiments, the first segment is configured to enable a latch mechanism to perform a cam in operation. In certain embodiments, the second segment is configured to enable a latch mechanism to perform a cam out operation. In certain embodiments, when the latch mechanism performs a cam in operation, a hook of the latch mechanism pushes against an inside surface of the first segment of the latch engagement portion. In certain embodiments, when the latch mechanism performs a cam out operation, the hook of the latch mechanism pushes against an outside surface of the second segment of the latch engagement portion.

In certain embodiments, the first segment and the second segment are configured to provide a latching mechanism with a height which substantially corresponds to a height of the hook of the latch mechanism. In certain embodiments, the first segment has a height corresponding to substantially half of the height of the latch engagement portion. In certain embodiments, the second segment has a height corresponding to substantially half of the height of the latch engagement portion. In certain embodiments, the first segment is vertically positioned along a top portion of the height of the latch engagement portion. In certain embodiments, the second segment is vertically positioned along a bottom portion of the latch engagement portion.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

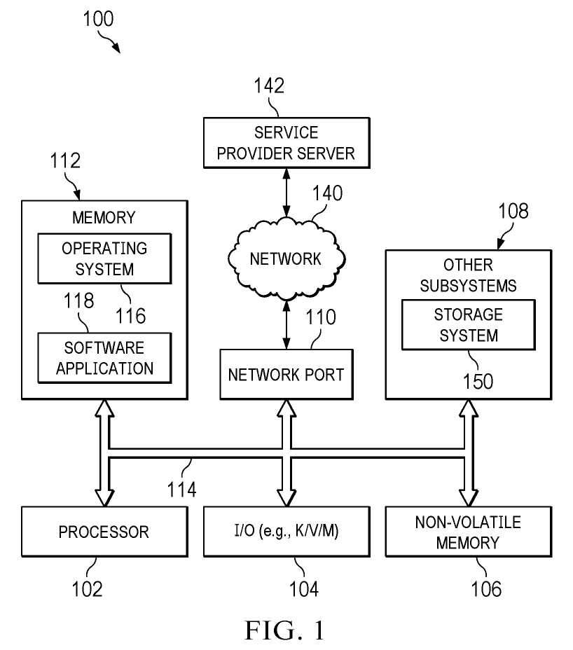

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include storage system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the storage system 150 comprises a storage system housing which includes a latch engagement portion which provides a depth feature that does not require an aperture to be punched through the storage system housing. As used herein, a depth feature broadly refers to providing a latch engagement portion with an inside edge and an outside edge with enough dimensional difference that a cam in and cam out function may be performed using the latch engagement portion. In certain embodiments, the latch engagement portion is configured to include a first segment and a second segment, where the first segment and the second segment combine to provide a depth feature. In certain embodiments, the first segment and the second segment provide a first contact surface and a second contact surface for a latching mechanism. In certain embodiments, the first segment provides the latch engagement portion with an inside contact surface for the latching mechanism. In certain embodiments, the second segment provides the latch engagement portion with an outside contact surface for a latching mechanism.

In certain embodiments, the first segment protrudes from a face of the storage system housing by a first amount, and the second segment protrudes from the face of the storage system housing by a second amount. In certain embodiments, the second amount is greater than the first amount. In certain embodiments, the first segment is configured to enable a latch mechanism to perform a cam in operation. In certain embodiments, the second segment is configured to enable a latch mechanism to perform a cam out operation. In certain embodiments, when the latch mechanism performs a cam in operation, a hook of the latch mechanism pushes against an inside surface of the first segment of the latch engagement portion. In certain embodiments, when the latch mechanism performs a cam out operation, the hook of the latch mechanism pushes against an outside surface of the second segment of the latch engagement portion.

In certain embodiments, the first segment and the second segment are configured to provide a latching mechanism with a height which substantially corresponds to a height of the hook of the latch mechanism. In certain embodiments, the first segment has a height corresponding to substantially half of the height of the latch engagement portion. In certain embodiments, the second segment has a height corresponding to substantially half of the height of the latch engagement portion. In certain embodiments, the first segment is vertically positioned along a top portion of the height of the latch engagement portion. In certain embodiments, the second segment is vertically positioned along a bottom portion of the latch engagement portion.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

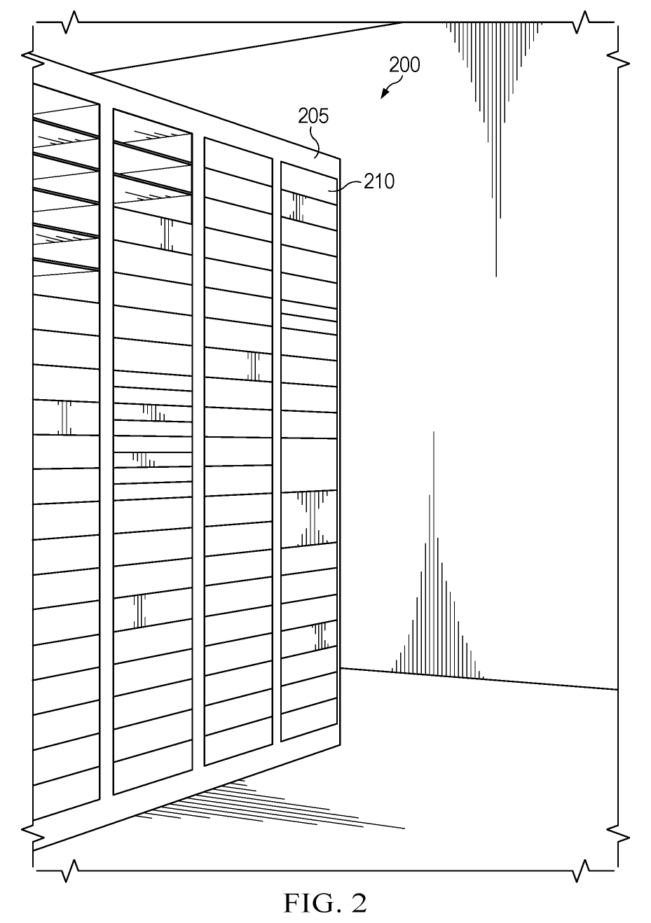

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

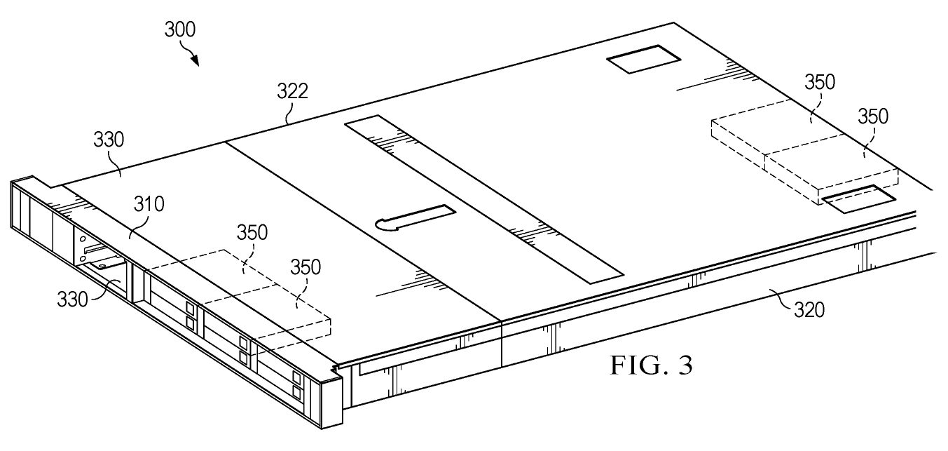

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system.

In certain embodiments, components mounted in one or more of the bays 310 include a storage system 350 which includes a latch engagement portion which provides a depth feature that does not require an aperture to be punched through the storage system housing. In certain embodiments, the latch engagement portion is configured to include a first segment and a second segment, where the first segment and the second segment combine to provide a depth feature. In certain embodiments, the first segment and the second segment provide a first contact surface and a second contact surface for a latching mechanism. In certain embodiments, the first segment provides the latch engagement portion with an inside contact surface for the latching mechanism. In certain embodiments, the second segment provides the latch engagement portion with an outside contact surface for a latching mechanism.

In certain embodiments, the first segment protrudes from a face of the storage system housing by a first amount, and the second segment protrudes from the face of the storage system housing by a second amount. In certain embodiments, the first segment is configured to enable a latch mechanism to perform a cam in operation. In certain embodiments, the second segment is configured to enable a latch mechanism to perform a cam out operation. In certain embodiments, when the latch mechanism performs a cam in operation, a hook of the latch mechanism pushes against an inside surface of the first segment of the latch engagement portion. In certain embodiments, when the latch mechanism performs a cam out operation, the hook of the latch mechanism pushes against an outside surface of the second segment of the latch engagement portion.

In certain embodiments, the first segment and the second segment are configured to provide a latching mechanism with a height which substantially corresponds to a height of the hook of the latch mechanism. In certain embodiments, the first segment has a height corresponding to substantially half of the height of the latch engagement portion. In certain embodiments, the second segment has a height corresponding to substantially half of the height of the latch engagement portion. In certain embodiments, the first segment is vertically positioned along a top portion of the height of the latch engagement portion. In certain embodiments, the second segment is vertically positioned along a bottom portion of the latch engagement portion.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

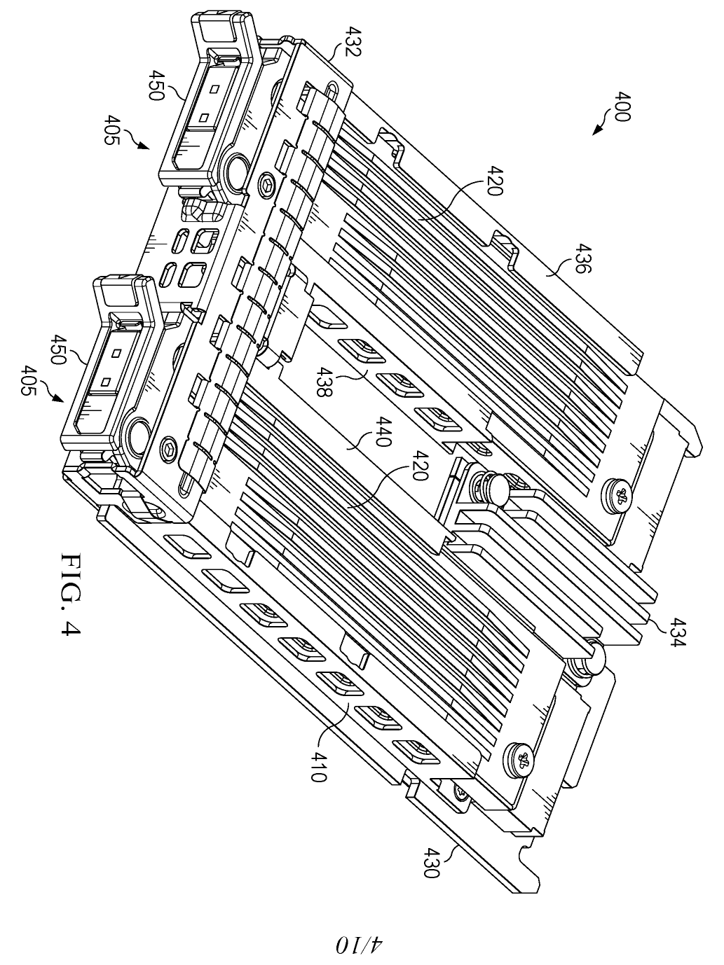

FIG. 4 shows a storage system 400 with a plurality of latching systems 405. In certain embodiments, the storage system 400 corresponds to storage system 150. In certain embodiments, each latching system 405 includes a latching mechanism and a latch engagement portion.

In certain embodiments, the storage system 400 corresponds to storage system 150. In certain embodiments the storage module housing 410 includes a bottom wall 430, a front housing portion 432, an outside right wall 434, an outside left wall 436, an inside right wall 438, an inside left wall 440, or a combination thereof.

In certain embodiments, the housing portion 432 extends substantially perpendicularly (i.e., +/- 20%) from the bottom wall 430. In certain embodiments, the front wall extends substantially perpendicularly (i.e., +/- 20%) from the bottom wall 430. In certain embodiments, the outside right wall 434 extends substantially perpendicularly (i.e., +/- 20%) from the bottom wall 430. In certain embodiments, the outside left wall 436 extends substantially perpendicularly (i.e., +/- 20%) from the bottom wall 430. In certain embodiments, the right inside wall 438 extends substantially perpendicularly (i.e., +/- 20%) from the bottom wall 430. In certain embodiments, the left inside wall 440 extends substantially perpendicularly (i.e., +/- 20%) from the bottom wall 430. It will be appreciated that the orientations of the walls will be reversed when the storage system is installed at the rear of the information handling systems (e.g., the front housing portion 432 is effectively a rear housing portion).

In certain embodiments, the front housing portion 432 defines one or more apertures via which storage cartridge modules 420 may be installed in the storage module housing 410. In certain embodiments pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 434 and the inside left wall 440 define channels via which a storage cartridge module 420 may be installed in the storage module housing 410. In certain embodiments, the outside left wall 436 and the inside right wall 438 define channels via which a storage cartridge module 420 may be installed in the storage module housing 410.

In certain embodiments, when the storage cartridge module 420 is configured in a hot swap storage media access configuration, each storage cartridge module 420 includes a respective latch 450 which allows a user to unlatch the storage cartridge module and remove the storage cartridge module from the storage system.

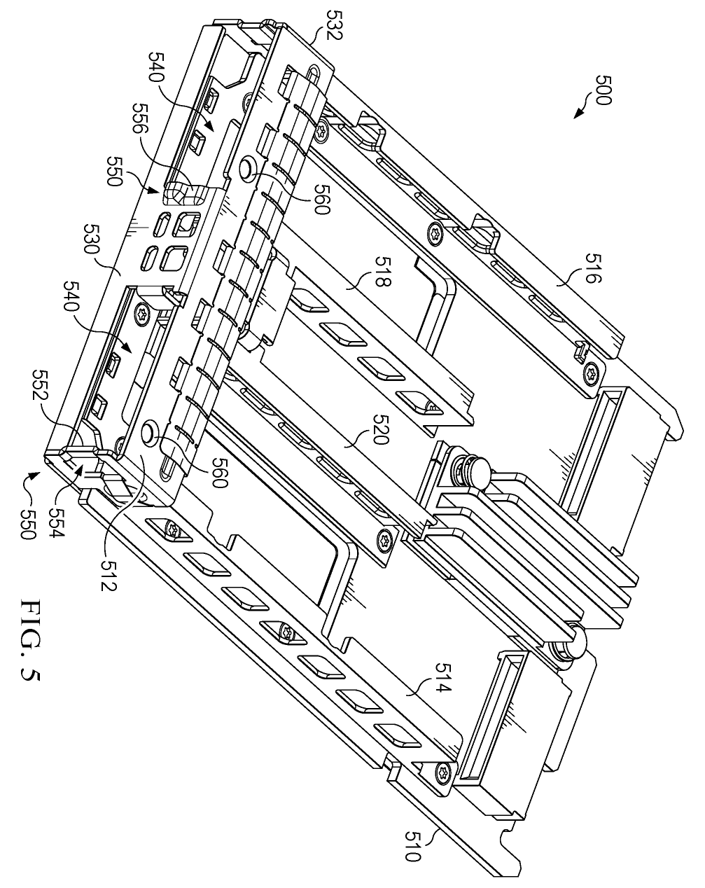

FIG. 5 shows a perspective view of a storage system housing 500 of a storage system. In certain embodiments, the storage system housing 500 corresponds to storage system housing 410. In certain embodiments, the storage system corresponds to storage system 150. In certain embodiments, the storage system housing 500 is designed to function with a boot optimized storage system.

In certain embodiments, the storage module housing 410 includes a bottom wall 510, a front housing portion 512, an outside right wall 514, an outside left wall 516, an inside right wall 518, an inside left wall 520, or a combination thereof. In certain embodiments, the front housing portion 512 extends substantially perpendicularly (i.e., +/- 20%) from the bottom wall 510. In certain embodiments, the front wall extends substantially perpendicularly (i.e., +/- 20%) from the bottom wall 510. In certain embodiments, the outside right wall 514 extends substantially perpendicularly (i.e., +/- 20%) from the bottom wall 510. In certain embodiments, the outside left wall 516 extends substantially perpendicularly (i.e., +/- 20%) from the bottom wall 510. In certain embodiments, the right inside wall 518 extends substantially perpendicularly (i.e., +/- 20%) from the bottom wall 510. In certain embodiments, the left inside wall 520 extends substantially perpendicularly (i.e., +/- 20%) from the bottom wall 510. It will be appreciated that the orientations of the walls will be reversed when the storage system is installed at the rear of the information handling systems (e.g., the front housing portion 512 is effectively a rear housing portion).

In certain embodiments, pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 514 and the inside left wall 520 define channels via which a storage cartridge module 420 may be installed in the storage module housing 410. In certain embodiments, the outside left wall 516 and the inside right wall 518 define channels via which a storage cartridge module 420 may be installed in the storage module housing 410.

In certain embodiments, the front housing portion 512 includes a housing portion front wall 530 and a housing portion top wall 532. In certain embodiments, the housing portion front wall 530 extends substantially perpendicularly (i.e., +/- 20%) from the bottom wall 510. In certain embodiments, the housing portion top wall 532 extends substantially perpendicularly (i.e., +/- 20%) from the housing portion top wall 530. In certain embodiments, the housing portion front wall 530 provides a customer facing surface.

In certain embodiments, the housing portion front wall 530 defines one or more apertures 540 via which storage cartridge modules may be installed in the storage module housing 410. In certain embodiments, each aperture 540 includes a respective latching portion 550. In certain embodiments, a latching portion 550 includes a latch tab 552 and a latch aperture 554 via which a latch mates. In certain embodiments, the latch tab 552 and the latch aperture 554 are located on an outside wall of the housing portion 512. In certain embodiments, a latching portion 550 includes a latch bump out 556 via which a latch mates. In certain embodiments, the latch bump out 556 is located on the front wall 530 of the housing portion 512. In certain embodiments, the housing portion top wall 532 defines one or more housing locking apertures 560. In certain embodiments, a fastener secures a storage cartridge module to the storage module housing 500 when the storage system is configured in a locking configuration. In certain embodiments, the latch tab 552 and the latch bump out 556 function as respective latch engagement portions. In certain embodiments, the latch tab 552 functions as a latch engagement portion having a corresponding latching configuration. In certain embodiments, the latch bump out 556 functions as a latch engagement portion having a corresponding latching configuration. In certain embodiments, the latching configuration of the latch tab 552 and the latching configuration of the latch bump out 556 are different latching configurations.

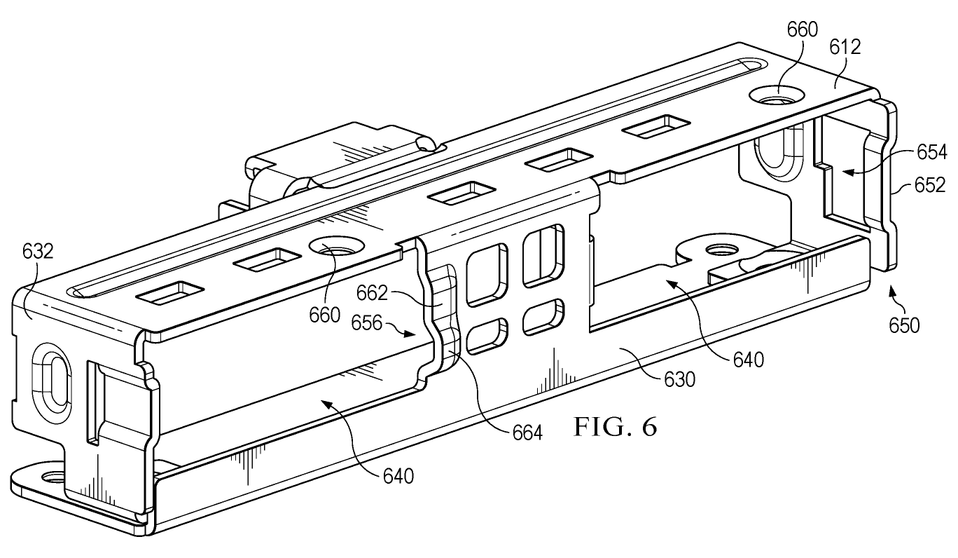

FIG. 6 shows a perspective view of a front housing component 600 of a storage system housing of a storage system. In certain embodiments, the front housing component 600 corresponds to front housing portion 512. In certain embodiments, the storage system housing corresponds to storage system housing 410. In certain embodiments, the storage system corresponds to storage system 150.

In certain embodiments, the front housing portion 612 includes a housing portion front wall 630 and a housing portion top wall 632. In certain embodiments, the housing portion front wall 630 extends substantially perpendicularly (i.e., +/- 20%) from the bottom wall 610. In certain embodiments, the housing portion top wall 632 extends substantially perpendicularly (i.e., +/- 20%) from the housing portion top wall 630. In certain embodiments, the housing portion front wall 630 provides a customer facing surface.

In certain embodiments, the housing portion front wall 630 defines one or more apertures 640 via which storage cartridge modules may be installed in the storage module housing 410. In certain embodiments, each aperture 640 includes a respective latching portion 650. In certain embodiments, a latching portion 650 includes a latch tab 652 and a latch aperture 654 via which a latch mates. In certain embodiments, the latch tab 652 and the latch aperture 654 are located on an outside wall of the housing portion 612. In certain embodiments, a latching portion 650 includes a latch bump out 656 via which a latch mates. In certain embodiments, the latch bump out 656 is located on the front wall 630 of the housing portion 612. In certain embodiments, the housing portion top wall 632 defines one or more housing locking apertures 660. In certain embodiments, a fastener secures a storage cartridge module to the storage module housing 600 when the storage system is configured in a locking configuration. In certain embodiments, the latch tab 652 and the latch bump out 656 function as respective latch engagement portions. In certain embodiments, the latch tab 652 functions as a latch engagement portion having a corresponding latching configuration. In certain embodiments, the latch bump out 656 functions as a latch engagement portion having a corresponding latching configuration. In certain embodiments, the latching configuration of the latch tab 652 and the latching configuration of the latch bump out 656 are different latching configurations.

In certain embodiments, the latch bump out 656 is configured to provide a latch engagement portion with a depth feature. In certain embodiments, the latch bump out 656 is configured to include a first segment 662 and a second segment 664, where the first segment 662 and the second segment 664 combine to provide a depth feature. In certain embodiments, the first segment 662 and the second segment 664 provide a first contact surface and a second contact surface for a latching mechanism. In certain embodiments, the first segment 662 provides the latch engagement portion with an inside contact surface for the latching mechanism. In certain embodiments, the second segment 664 provides the latch engagement portion with an outside contact surface for a latching mechanism.

In certain embodiments, the first segment 664 protrudes from a face 530 of the storage system housing 600 by a first amount, and the second segment protrudes from the face of the storage system housing by a second amount. In certain embodiments, the first segment 662 is configured to enable a latch mechanism to perform a cam in operation. In certain embodiments, the second segment 664 is configured to enable a latch mechanism to perform a cam out operation. In certain embodiments, when the latch mechanism performs a cam in operation, a hook of the latch mechanism pushes against an inside surface of the first segment of the latch engagement portion. In certain embodiments, when the latch mechanism performs a cam out operation, the hook of the latch mechanism pushes against an outside surface of the second segment of the latch engagement portion.

In certain embodiments, the first segment 662 and the second segment 664 are configured to provide a latching mechanism with a latch engagement portion height which substantially corresponds to a height of the hook of the latch mechanism. In certain embodiments, the first segment 662 has a height corresponding to substantially half of the height of the latch engagement portion. In certain embodiments, the second segment 664 has a height corresponding to substantially half of the height of the latch engagement portion. In certain embodiments, the first segment 662 is vertically positioned along a top portion of the height of the latch engagement portion. In certain embodiments, the second segment 664 is vertically positioned along a bottom portion of the latch engagement portion.

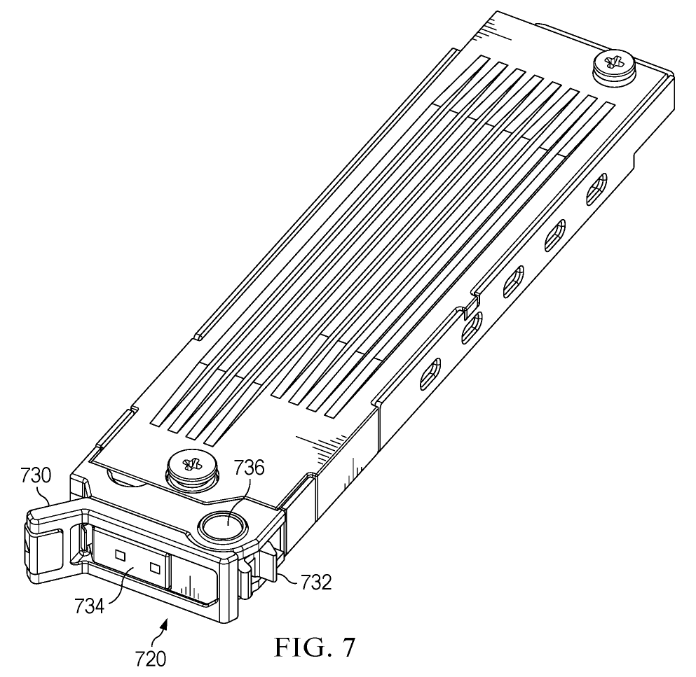

FIG. 7 shows a perspective view of a storage cartridge 700 of a storage system. In certain embodiments, the storage cartridge module 700 corresponds to storage cartridge module 420. In certain embodiments, the storage system corresponds to storage system 150.

In certain embodiments the storage cartridge module 700 includes a bottom component 710 and a top cover 712. In certain embodiments, the bottom component 710 and the top cover 712 are common to the storage cartridge module 700 when the storage cartridge module 700 is configured in a hot swap storage media access configuration.

In certain embodiments, the bottom component 710 and the top cover 712 are configured to receive a latch component 730. In certain embodiments, the bottom component 710 defines an attachment aperture, includes an attachment component, or a combination thereof. In certain embodiments, the attachment component includes a nut. In certain embodiments, the attachment aperture, the attachment component, or a combination thereof, are used to attach a latch component 730 to the storage cartridge module 700. In certain embodiments, the attachment component mates with a fastener to mount the top cover 712 to the bottom component 710.

In certain embodiments, a latch mechanism includes a latch hook portion 732. In certain embodiments, the latch 730 and the latch hook portion 732, or a combination thereof are included within a latch mechanism. In certain embodiments, the latch hook portion 732 is configured to interact with a latch engagement portion.

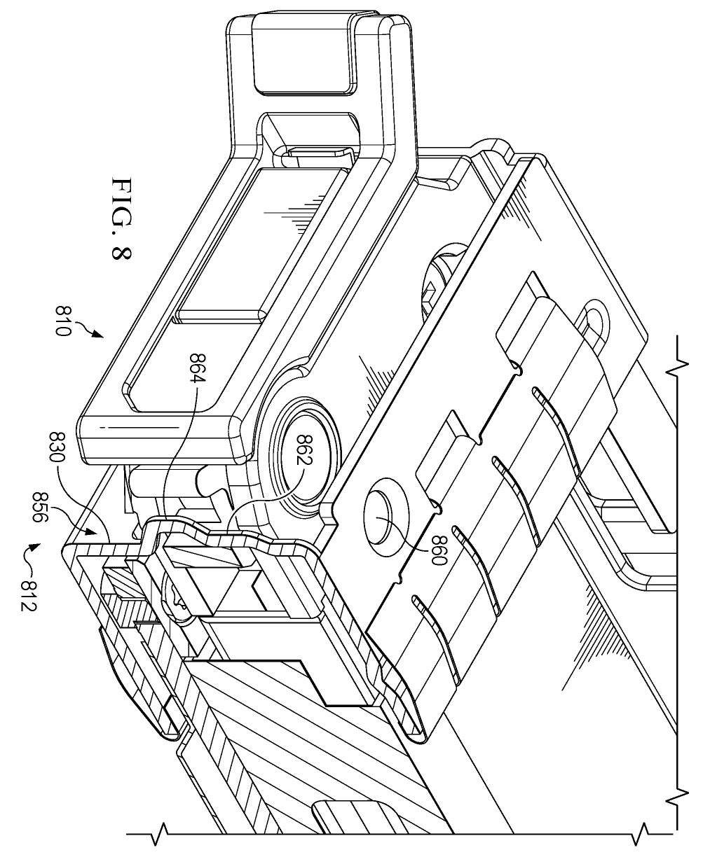

FIG. 8 shows a cut away perspective view of a portion of a storage system latching system 800. In certain embodiments, the latching system 800 is one example of a latching system of the storage system 400. In certain embodiments, the latching system 800 includes a latching mechanism 810 and a latch engagement portion 812.

In certain embodiments, the latch engagement portion 812 includes a latch bump out 856 via which the latching mechanism 810 mates. In certain embodiments, the latch bump out 856 is located on the front wall 830 of a housing portion. In certain embodiments, the latch bump out 856 functions as a latch engagement portion. In certain embodiments, the latch bump out 856 functions as a latch engagement portion having a corresponding latching configuration.

In certain embodiments, the latch bump out 856 is configured to include a first segment 962 and a second segment 864, where the first segment 962 and the second segment 864 combine to provide a depth feature. In certain embodiments, the first segment 962 and the second segment 864 provide a first contact surface and a second contact surface for a latching mechanism. In certain embodiments, the first segment 962 provides the latch engagement portion with an inside contact surface for the latching mechanism. In certain embodiments, the second segment 864 provides the latch engagement portion with an outside contact surface for a latching mechanism.

In certain embodiments, the first segment 864 protrudes from a face 830 of the storage system housing 800 by a first amount, and the second segment protrudes from the face of the storage system housing by a second amount. In certain embodiments, the first segment 962 is configured to enable a latch mechanism to perform a cam in operation. In certain embodiments, the second segment 864 is configured to enable the latch mechanism 810 to perform a cam out operation. In certain embodiments, when the latch mechanism 810 performs a cam in operation, a hook 832 of the latch mechanism pushes against an inside surface of the first segment 962 of the latch engagement portion 812. In certain embodiments, when the latch mechanism 810 performs a cam out operation, the hook 832 of the latch mechanism 810 pushes against an outside surface of the second segment 864 of the latch engagement portion.

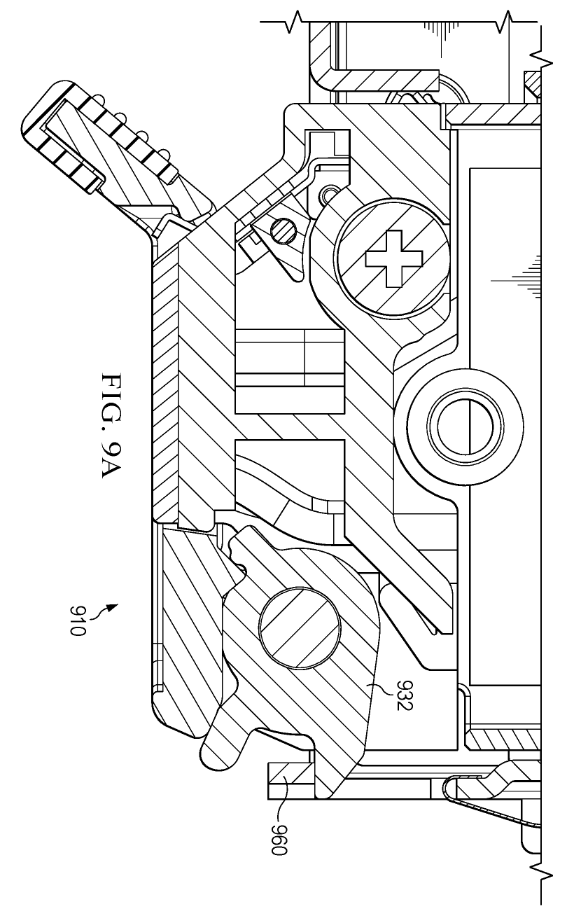

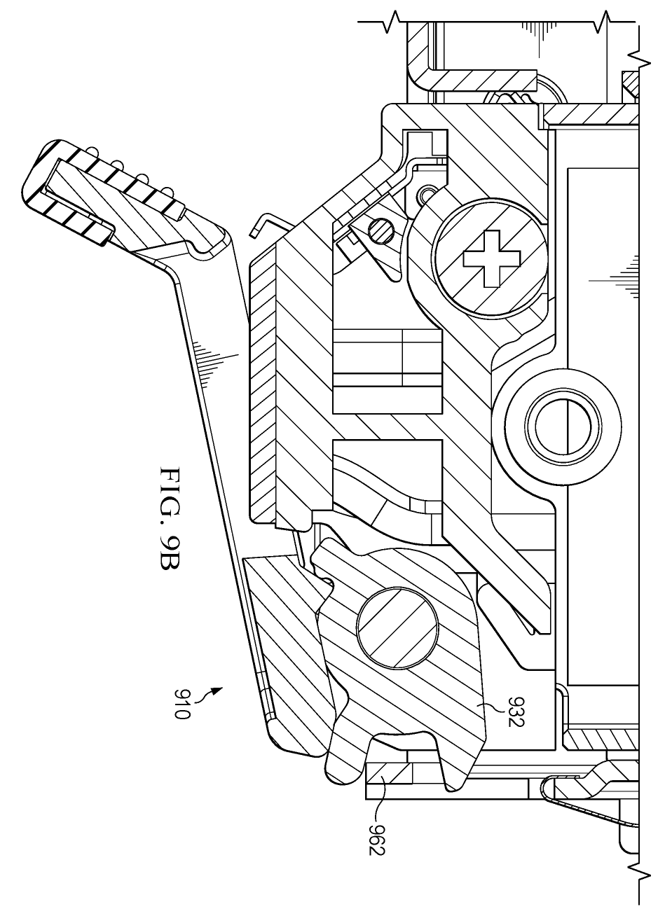

FIG. 9A and 9B, generally referred to as FIG. 9, show cross sectional views of a latching system 900 when performing an installation operation and a removal operation, respectively.

In certain embodiments, the first segment 960 is configured to enable a latch mechanism to perform a cam in operation. In certain embodiments, the cam in operation is used when performing an installation operation (see e.g., FIG. 9A). In certain embodiments, the second segment 962 is configured to enable the latch mechanism 910 to perform a cam out operation. In certain embodiments, the cam out operation is used when performing a removal operation (see e.g., FIG. 9B). In certain embodiments, when the latch mechanism 910 performs a cam in operation, a hook 932 of the latch mechanism pushes against an inside surface of the first segment 960 of the latch engagement portion 912. In certain embodiments, when the latch mechanism 910 performs a cam out operation, the hook 932 of the latch mechanism 910 pushes against an outside surface of the second segment 962 of the latch engagement portion.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

1. A storage system housing for use with a storage system for an information handling system, comprising:
a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

2. The storage system housing of claim 1, wherein:
the latch engagement portion comprises a latch bump out, the latch bump out being configured to provide the latch engagement portion with a depth feature.

3. The storage system housing of claim 2, wherein:
the latch bump out comprises a first segment and a second segment, the first segment providing a first contact surface for the latching mechanism and the second segment providing a second contact surface for the latching mechanism.

4. The storage system housing of claim 3, wherein:
the first contact surface corresponds to an inside contact surface for the latching mechanism and the second surface corresponds to an outside contact surface for the latching mechanism.

5. The storage system housing of claim 3, wherein:
the first segment protrudes from the front housing portion by a first amount;
the second segment protrudes from the front housing portion by a second amount; and,
the second amount is greater than the first amount.

6. The storage system housing of claim 3, wherein:
the first segment and the second segment combined have a latch engagement portion height, the height corresponding to a height of hook of the latching mechanism.

7. A storage system comprising:
a storage system cartridge module; and,
a storage system housing, the storage system housing comprising
a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

8. The storage system of claim 7, wherein:
the latch engagement portion comprises a latch bump out, the latch bump out being configured to provide the latch engagement portion with a depth feature.

9. The storage system of claim 8, wherein:
the latch bump out comprises a first segment and a second segment, the first segment providing a first contact surface for the latching mechanism and the second segment providing a second contact surface for the latching mechanism.

10. The storage system of claim 9, wherein:
the first contact surface corresponds to an inside contact surface for the latching mechanism and the second surface corresponds to an outside contact surface for the latching mechanism.

11. The storage system of claim 9, wherein:
the first segment protrudes from the front housing portion by a first amount;
the second segment protrudes from the front housing portion by a second amount; and,
the second amount is greater than the first amount.

12. The storage system of claim 9, wherein:
the first segment and the second segment combined have a latch engagement portion height, the height corresponding to a height of hook of the latching mechanism.

13. A system comprising:
a chassis;
a processor contained within the chassis;
a data bus coupled to the processor; and,
a storage system comprising
a storage system cartridge module; and,
a storage system housing, the storage system housing comprising
a front housing portion, the front housing portion extending substantially perpendicularly, the front housing portion comprising a latch engagement portion, the latch engagement portion being positioned within the front housing portion, the latch engagement being configured to interact with a latching mechanism when a storage device is being one of installed and removed from the storage system.

14. The system of claim 13, wherein:
the latch engagement portion comprises a latch bump out, the latch bump out being configured to provide the latch engagement portion with a depth feature.

15. The system of claim 14, wherein:
the latch bump out comprises a first segment and a second segment, the first segment providing a first contact surface for the latching mechanism and the second segment providing a second contact surface for the latching mechanism.

16. The system of claim 15, wherein:
the first contact surface corresponds to an inside contact surface for the latching mechanism and the second surface corresponds to an outside contact surface for the latching mechanism.

17. The system of claim 15, wherein:
the first segment protrudes from the front housing portion by a first amount;
the second segment protrudes from the front housing portion by a second amount; and,
the second amount is greater than the first amount.

18. The system of claim 15, wherein:
the first segment and the second segment combined have a latch engagement portion height, the height corresponding to a height of hook of the latching mechanism.
